(19) United States
(12) Patent Application Publication
(10) Pub. No.: US 2025/0183147 A1
(43) Pub. Date: Jun. 5, 2025

(54) SEMICONDUCTOR PACKAGE

(71) Applicant: Samsung Electronics Co., Ltd., Suwon-si (KR)

(72) Inventor: Hongjin Kim, Suwon-si (KR)

(21) Appl. No.: 18/772,310

(22) Filed: Jul. 15, 2024

(30) Foreign Application Priority Data
Dec. 5, 2023 (KR) 10-2023-0174003

(51) Int. Cl. H01L 23/498; H01L 23/00; H01L 23/528; H01L 25/18; H10B 80/00

(52) U.S. Cl. CPC H01L 23/49838; H01L 23/49822; H01L 23/5286; H01L 24/48; H01L 24/16; H01L 24/32; H01L 24/73; H01L 25/18; H01L 2224/16225; H01L 2224/32145; H01L 2224/32225; H01L 2224/32245; H01L 2224/48147; H01L 2224/48227; H01L 2224/73253; H01L 2224/73265; H01L 2225/06506; H01L 2225/0651; H01L 2225/06562; H01L 2924/1431; H10B 80/00

(57) ABSTRACT

A semiconductor package includes a substrate including terminals and a first conductive layer electrically connected to the terminals, bonding wires having one ends electrically connected to the terminals, and a semiconductor chip on an upper side of the substrate and having a structure in which pads electrically connected to other ends of the bonding wires are disposed on an upper surface. The substrate further includes a second conductive layer overlapping a portion of the wiring circuit layer in a vertical direction, and the lower conductive layer includes a through-hole in a region overlapping the terminals in the vertical direction.

### CROSS-REFERENCE TO RELATED APPLICATION(S)

This application claims the benefit under 35 USC 119 (a) of Korean Patent Application No. 10-2023-0174003 filed on Dec. 5, 2023 in the Korean Intellectual Property Office, the entire disclosure of which is incorporated herein by reference for all purposes.

### BACKGROUND

The present inventive concept relates to a semiconductor package.

Recently, there has been a demand for increased performance and increased capacity of semiconductor packages installed in electronic devices. Accordingly, semiconductor packages, in which a plurality of semiconductor chips are embedded together, are being developed, and the data transmission speed of signals transmitted and received between the plurality of semiconductor chips is gradually increasing. Accordingly, the quality of the transmitted/received signals and power of semiconductor chips is also becoming increasingly important.

### SUMMARY

Example embodiments provide a semiconductor package in which the quality (for example, at least one of slope distortion, phase distortion, signal integrity, power integrity, and possible data transmission speed) of transmitted/received signals or power of a semiconductor chip may be improved.

According to example embodiments, a semiconductor package includes a substrate. The substrate includes conductive lines, bonding fingers, and a wiring circuit region. The wiring circuit region is disposed lower than the bonding fingers. The semiconductor package further includes bonding wires and a first semiconductor chip on the substrate. The first semiconductor chip includes pads disposed on an upper surface thereof, and each of the pads is electrically connected to a first end of a corresponding one of the bonding wires. The wiring circuit region includes a conductive layer and at least a portion of an insulating layer, the conductive layer and the portion of the insulating layer are disposed at a first height level, and the conductive layer and the portion of the insulating layer are coplanar with each other. Each of second ends of the bonding wires is electrically connected to a corresponding one of the bonding fingers. The portion of the insulating layer overlaps the bonding fingers in a vertical direction, and the conductive layer overlaps at least a portion of the conductive lines in the vertical direction.

According to example embodiments, a semiconductor package includes a substrate. The substrate includes bonding fingers, conductive lines and a conductive layer including a through-opening. Each of the conductive lines is electrically connected to a corresponding one of the bonding fingers. The semiconductor package further includes a first semiconductor chip on the substrate and electrically connected to the bonding fingers. The through-opening overlaps the bonding fingers in a vertical direction. The bonding fingers are arranged repeatedly in a row in a first direction. A length of the through-opening in the first direction is longer than a length of the through-opening in a second direction, perpendicular to the first direction.

According to example embodiments, a semiconductor package includes a substrate. The substrate includes bonding fingers arranged repeatedly in a row in a first direction and conductive lines. Each of the conductive lines is electrically connected to a corresponding one of the bonding fingers. The substrate further includes a conductive layer overlapping a portion of the conductive lines in a vertical direction. The conductive layer includes a through-hole overlapping the bonding fingers in the vertical direction. The substrate further includes an insulating layer. At least portion of the insulating layer and the conductive layer are disposed at the same height level. The substrate further includes external connection terminals disposed to be lower than the conductive layer, and external connection lines electrically connected to the external connection terminals. The external connection lines does not overlap the through-hole in the vertical direction. The semiconductor package further includes bonding wires. Each of which having a first end electrically connected to a corresponding one of the bonding fingers. The semiconductor package further includes a first semiconductor chip on the substrate. The first semiconductor chip including pads. Each of the pads is electrically connected to a second end of a corresponding one of the bonding wires. The bonding fingers include a plurality of signal bonding fingers, through each of which a signal is transmitted or received by the first semiconductor chip. The bonding fingers include a power bonding finger through which power is supplied to the first semiconductor chip. The through-hole overlaps, in the vertical direction, a region between the power bonding finger and an adjacent signal bonding finger and a region between the plurality of signal bonding fingers, and an area of the through-hole of the conductive layer is smaller than an area of a remaining portion of the second conductive layer in a plane view.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1A and 1B are diagrams schematically illustrating electrical connection relationships within a semiconductor package according to an example embodiment;

FIG. 2A is a perspective view schematically illustrating a physical connection relationship of some components of a semiconductor package according to an example embodiment;

FIG. 2B is a perspective view schematically illustrating an electrical connection relationship of some components of FIG. 2A;

FIG. 3 is a perspective view illustrating at least a portion of a semiconductor package according to an example embodiment;

FIGS. 4A and 4B are perspective views illustrating at least a portion of a semiconductor package according to an example embodiment;

FIGS. 5A and 5B are perspective views illustrating at least a portion of a semiconductor package according to an example embodiment; and

FIGS. 6A to 6D are cross-sectional views illustrating a semiconductor package according to an example embodiment.

### DETAILED DESCRIPTION

The detailed description aspects of the present inventive concept described below refers to the accompanying drawings, which illustrate, by way of example, specific embodiments in which the present inventive concept may be practiced. These embodiments are described in sufficient detail to enable those skilled in the art to practice the present inventive concept. It should be understood that the various embodiments are different from one another but are not necessarily mutually exclusive. For example, specific shapes, structures and characteristics described herein with respect to an example embodiment may be implemented in other embodiments without departing from the spirit and scope of the present inventive concept. Additionally, it should be understood that the location or arrangement of individual components within each disclosed embodiment may be changed without departing from the spirit and scope of the present inventive concept. Accordingly, the detailed description below is not intended to be taken in a limiting sense, and the scope of the present invention is limited only by the appended claims, together with all equivalents asserted in those claims. Similar reference numbers in the drawings refer to identical or similar functions across various aspects.

Below, in order to enable those skilled in the art to easily practice the present invention, embodiments will be described in detail with reference to the attached drawings.

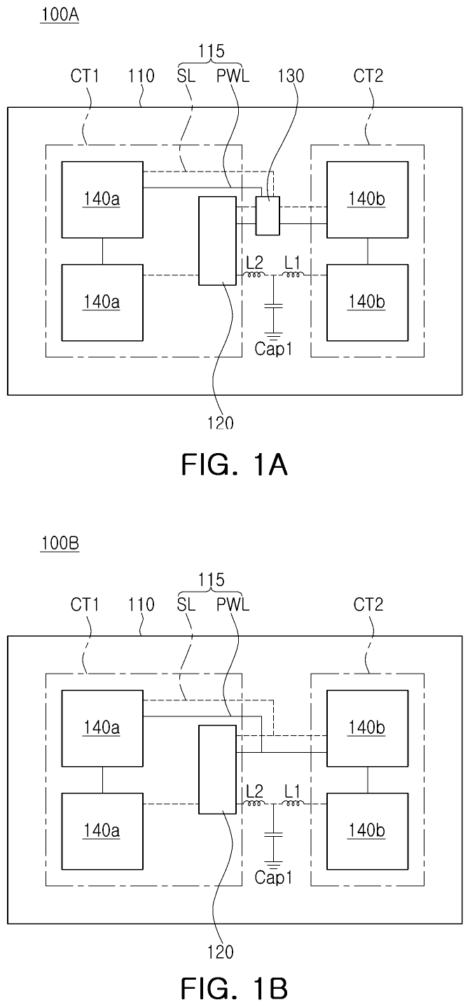

FIGS. 1A, 2A, 2B, and 6A illustrate a semiconductor package 100A according to an example embodiment. The semiconductor package 100A may include a substrate 110, bonding wires BW, and chip sets CT1 and CT2. The chip sets CT1 and CT2 may include a first chip set CT1 and a second chip set CT2. Each of chip set CT1 and chip set CT2 may include one or more semiconductor chips. For example, the first chip set CT1 may include a plurality of first semiconductor chips 120, 140a and the second chip set CT2 may include a plurality of second semiconductor chips 140b.

The first semiconductor chip 120 disposed lowest among the plurality of first semiconductor chips 120 and 140a may be a controller chip, although the scope of the embodiments is not limited in this respect. For example, the controller chip may receive or transmit a signal to the outside (for example, processor) of the semiconductor package 100A through the external connection terminals 110P and package bumps 170 of the substrate 110. In another embodiment, one of semiconductor chips 140a and 140b may be the controller chip. In this case, the lowest semiconductor chip 120 may be a memory chip.

As used herein, unless otherwise noted, spatially relative terms, such as “lower,” “upper,” “top,” “bottom,” any form thereof and the like, with respect to an element is defined on the basis of the Z-direction.

The lowest controller chip 120 may be a host for the semiconductor chips 140a and 140b (also collectively denoted as 140), and may receive or transmit signals from or to the semiconductor chips 140a and 140b through a host interface. For all semiconductor chips included in the chip sets CT1 and CT2, the host interface may be Universal Flash Storage (UFS), but is not limited thereto. For example, the host interface may be at least one of Peripheral Component Interconnect Express (PCIe), Non-Volatile Memory Express (NVMe), Serial Attached SCSI (SAS), Small Computer System Interface (SCSI), SCSIe, Serial Advanced Technology Attachment (SATA), SATAe, Computer Express Link (CXL), and Gen-Z.

For example, the semiconductor chips 140a and 140b may include multiple (for example, 4) channels (or memory banks), and the plurality of channels (or memory banks) may transmit or receive signals to the controller chip in parallel. The physical positional relationship of the semiconductor chips 120, 140a and 140b may vary depending on the design (for example, number of channels, number of semiconductor chips, size/thickness/area of semiconductor package, and the like).

The semiconductor chips 140a and 140b may be volatile memories (for example, SRAM (Static Random Access Memory), DRAM (Dynamic RAM), SDRAM (Synchronous RAM), and the like) or non-volatile memories (flash memory, PRAM (Phase-change RAM), MRAM (Magneto-resistive RAM), ReRAM (Resistive RAM), FRAM (Ferro-electric RAM), RRAM (Resistive Random Access Memory), FeRAM (Ferroelectric Random Access) Memory), and the like), but are not limited to memory semiconductor chips. For example, the chip sets CT1 and CT2 may be replaced with a plurality of non-memory chips, and the controller chip may transmit or receive signals to a plurality of non-memory chips through a chiplet interface such as Universal Chip Interconnect Express (UCIe).

A spacer 150 that may be included in the semiconductor package 100A. The spacer 150 may be disposed between the lowest first semiconductor chip 120 and the other first semiconductor chips 140a. For example, the spacer 150 may be a dummy silicon spacer chip and may be disposed in a similar manner to the plurality of first semiconductor chips 120 and 140a. The spacer 150 may not have any electrical function, for example, transmitting or receiving signals and receiving power. The size or shape of the spacer 150 may vary depending on the physical positional relationship of the chip sets CT1 and CT2, and the spacer 150 may be omitted depending on the design.

The encapsulant 160, such as an epoxy molding compound (EMC) that may be included in the semiconductor package 100A, fills the space on the upper surface of the substrate 110 not occupied by the chip sets CT1 and CT2, and therefore, chip sets CT1 and CT2 may be sealed. The lowest first semiconductor chip 120 may be mounted on the substrate 110 with a flip-chip bonding structure. The flip-chip bonding structure may be a structure in which chip bumps CB disposed between the lower surface of the lowest first semiconductor chip 120 and the upper surface of the substrate 110 electrically connect the lowest first semiconductor chip 120 and the upper surface of the substrate 110. The flip-chip bonding structure may be omitted depending on design.

The melting point of the bumps CB and 170 may be lower than the melting point of a first conductive layer of a first wiring circuit region 115. For example, the bumps CB and 170 may include lead (Pb), bismuth (Bi), tin (Sn), an alloy (Sn—Ag—Cu) containing tin (Sn), and the like, but are not limited thereto. Each of the bumps CB and 170 may be in the form of lands, balls, or pins, and may include a single layer or multiple layers. For example, the bumps CB and 170 may be solder balls. At a temperature higher than the melting point, the bumps CB and 170 may be in a fluid state by a reflow process or a thermal compression bonding (TCB) process. Thereafter, as the temperature decreases, the bumps CB and 170 may be electrically connected to the substrate 110 and adhered to the substrate 110.

Among the semiconductor chips included in the chip sets CT1 and CT2, the wire-bonded semiconductor chips 140 (i.e., 140a and 140b) may be, by using a wire bonding process, electrically connected to the substrate 110 through bonding wires BW.

The wire-bonded semiconductor chips 140 may be attached to each other in a vertical direction (for example, Z-direction) on the upper surface of the substrate 110 through an adhesive film DF. Accordingly, the wire-bonded semiconductor chip 140 may not provide electrical connection paths on its lower surface. The wire-bonded semiconductor chip 140 may include signal pads SP and power pads PP arranged along an edge of the top surface of the wire-bonded semiconductor chip 140. The signal pads SP may be electrical paths through which signals may be transmitted or received by the wire-bonded semiconductor chip 140. The power pads PP may be electrical paths through which power is supplied to the wire-bonded semiconductor chip 140.

One end (e.g. a first end) of each of the bonding wires BW may be electrically connected to a corresponding one of the signal pads SP and power pads PP, and the other end (e.g., a second end) of each of the bonding wires BW may be electrically connected to a corresponding one of terminals (also referred to as bonding fingers) SGP and PWP of the substrate 110. Each of the signal pads SP and the power pads PP may be electrically connected to one end of at least a corresponding one of the bonding wires BW. Accordingly, each of the signal pads SP and the power pads PP of the wire-bonded semiconductor chip 140 may be electrically connected to at least a corresponding one of the terminals SGP and PWP of the substrate 110. The bonding wires BW may contain highly conductive metal materials such as gold (Au), aluminum (Al), and copper (Cu). The pads SP and PP and terminals SGP and PWP may not overlap each other in the vertical direction (for example, Z-direction). All of the signal pads SP, the power pads PP and the terminals SGP and PWP may be upwardly exposed in the Z-direction so that the signal pads SP and/or the power pads PP may not be disposed directly facing the terminals SGP and PWP. Accordingly, each of the bonding wires BW may have a curved extension shape to form electrical connection paths

As used herein, it will be understood that when a particular element is entirely within another element in a plane view as seen in a direction, the other element “entirely overlaps” the particular element in the direction. When a particular element is not entirely within another element but only a portion of the particular element is within the other element in a plane view as seen in a direction, the other element “partially overlaps” the particular element in the direction. When two elements both substantially entirely overlap each other in a plan view as seen in a direction, they are described as “mutually entirely overlapping” each other as seen in the direction. When an element is referred to as “overlapping” or “at least partially overlapping” another element, the element “entirely overlaps” or “partially overlaps” the other element.

The substrate 110 may have a structure in which a plurality of metal layers (also referred to as conductive layers) and a plurality of insulating layers are alternately stacked, like a printed circuit board, and at least one of the plurality of metal layers may include the first conductive layer of the first wiring circuit region 115. The first wiring circuit region 115 allows signals to be transmitted or received between the first semiconductor chip set CT1 and the second chip set CT2. The first wiring circuit region 115 may include a first conductive layer (designated symbols SGP, PWP, SL and PWL) and at least a portion of a first insulating layer (not shown in the drawings). The first conductive layer and the portion of the first insulating layer may be disposed at a first height level. The first conductive layer and the portion of the first insulating layer are coplanar with each other. The first conductive layer may include first conductive lines SL and PWL, and terminals SGP and PWP. The portion of the first insulating layer may be disposed in a portion of the first wiring circuit region 115 in which the first conductive layer is not formed in a plane view. The first conductive layer and the portion of the first insulating layer are coplanar.

The first conductive lines SL and PWL may include signal lines SL through which signals may be transmitted or received by the chip sets CT1 and CT2, and power lines PWL through which power may be supplied to chip sets CT1 and CT2. The signal lines SL may be directly connected to the signal terminals SGP (also referred to as signal bonding fingers), and the power lines PWL may be directly connected to power terminals PWP (also referred to as power bonding fingers).

The terminals SGP and PWP may include signal terminals SGP and/or power terminals PWP, and may be included in the uppermost metal layer among the plurality of metal layers of the substrate 110. Among the plurality of insulating layers of the substrate 110, the highest (i.e., topmost) insulating layer may be formed of solder resist, through which a plurality of fine openings may be formed. The terminals SGP and PWP may be exposed to the upper side of the substrate 110 through the plurality of openings, and may therefore contact the other ends of the bonding wires BW. The terminals SGP and PWP may be repeatedly arranged in a row arranged in a first direction (for example, Y-direction) and may be defined as bonding fingers. The term “contact,” “contacting,” “contacts,” or “in contact with,” as used herein, refers to a direct connection (i.e., touching) unless the context clearly indicates otherwise.

The bonding wires BW may have a parasitic inductance L1, and the first conductive lines SL and PWL may have a parasitic inductance L2. The terminals SGP and PWP may have a parasitic capacitance Cap1. Since the width of the terminals SGP and PWP may be larger than the width of the first conductive lines SL and PWL, the parasitic capacitance Cap1 may not be small. Since the bonding wires BW may have a curved shape or extend long, the parasitic inductance L1 may not be small.

The wire-bonded semiconductor chip 140 may be required to have a high data transfer rate (i.e., an amount of data to be transmitted and received per unit time). For example, when the wire-bonded semiconductor chip 140 transmits or receives a signal according to a control method for a UFS standard version 3.1 or lower, a data transfer rate of 12 Gbps is required. For example, a control method for a UFS standard version 5.0 may require a data transfer rate of 24 Gbps, and a control method for a UFS standard of higher than the version 5.0 may require data transfer rates higher than 24 Gbps.

The faster the data transmission speed of the signal, the shorter the period in which the signal value rises/falls, and the steeper (higher) the slope in which the signal value rises/falls. The larger the parasitic capacitance Cap1 and/or parasitic inductance (L1, L2), the lower the slope. Under the condition that the parasitic inductances L1 and L2 are not small, the slope may be steeper by reducing the parasitic capacitance Cap1. Alternatively, as the parasitic capacitance Cap1 increases, the phase distortion of the signal may also increase. Reducing the phase distortion of the signal may be implemented by reducing the parasitic capacitance Cap1.

For example, the signal terminals SGP and signal lines SL may be configured to pass on signals having a data transmission rate of 10 Gbps or more. For example, the minimum value of the slope, at which the signal passing through the signal terminals SGP and the signal lines SL rises/falls, may be determined to prevent significant distortion of a signal having a data transmission speed of 10 Gbps or more. The parasitic capacitance Cap1 and/or parasitic inductance (L1, L2) may be determined based on the minimum value of the slope and implemented by reducing the parasitic capacitance Cap1.

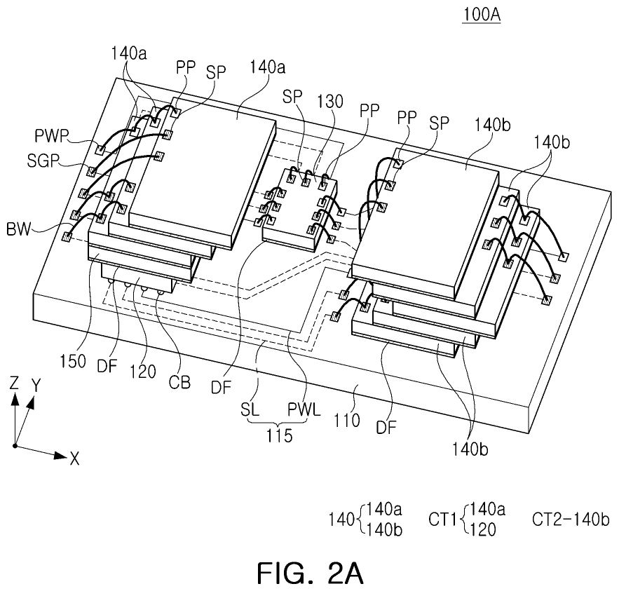

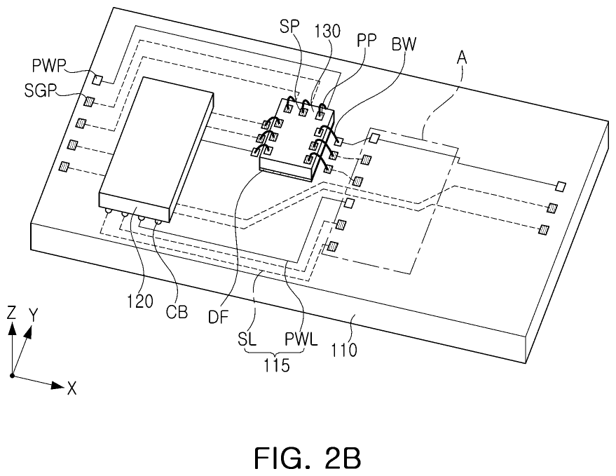

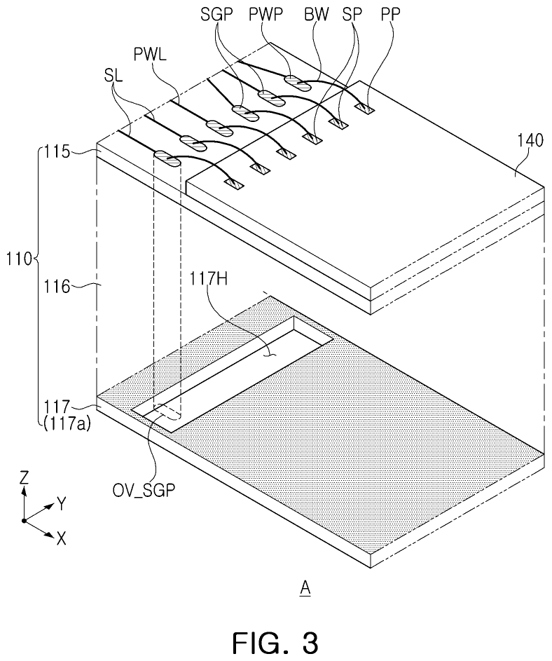

FIG. 3 is a perspective view illustrating a portion A of FIG. 2B.

Referring to FIG. 3, the substrate 110 may include a second wiring circuit region 117 overlapping the first wiring circuit region 115 in the vertical direction (for example, Z-direction), and the second wiring circuit region 117 may include a through-hole 117H (also described more generally as a through-opening) in the area (OV_SGP) overlapping the terminals SGP and PWP in the vertical direction (for example, Z-direction). The second conductive layer may overlap the pads PP and SP of the first semiconductor chip.

The second wiring circuit region 117 may include a second conductive layer, the through-hole 117H in the area (OV_SGP) and at least a portion of a second insulating layer (not shown in the drawings). The second conductive layer and the portion of the second insulating layer may be disposed at a second height level. The second height level is lower than the first height level in the vertical direction. The second conductive layer and the portion of the second insulating layer are coplanar with each other. The portion of the second insulating layer may be disposed in a portion of the second wiring circuit region 117 in which the second conductive layer is not formed in a plane view. The second conductive layer and the portion of the second insulating layer are coplanar.

For example, the second wiring circuit region 117 may include a ground plate (also referred to as a second conductive layer) that is electrically grounded and in the form of a plate. The second conductive layer may consist of only a single piece of ground plate. The through-hole 117H may be an area in the second wiring circuit region 117 where the second conductive layer is not disposed, and may be surrounded by the ground plate. The portion of the second insulating layer may be disposed in the through-hole 117H. The boundary line of the through-hole 117H may be formed by a partial boundary line of the ground plate and/or a partial boundary line of additional wirings.

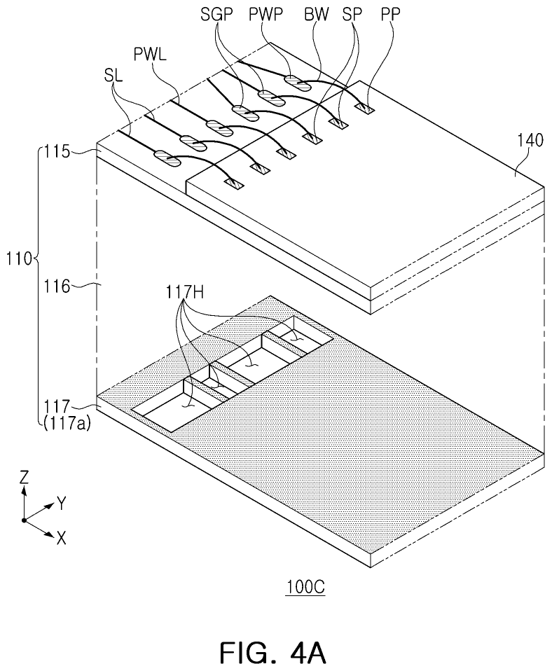

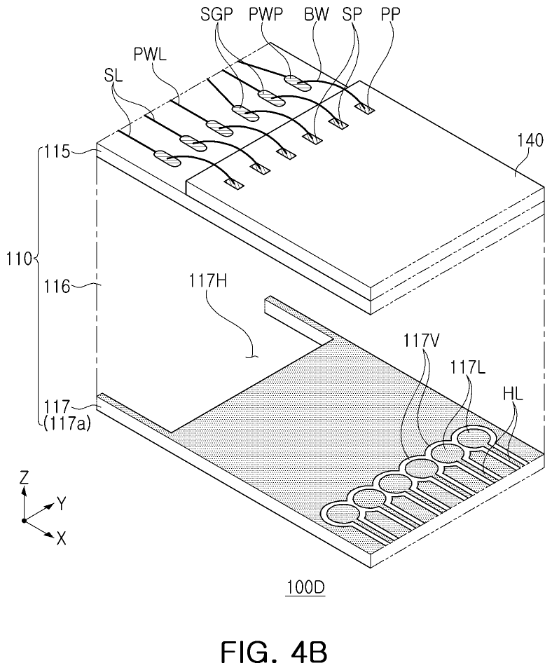

In an alternative embodiment, the second wiring circuit region 117 may further include additional wirings as well as the ground plate. For example, the second wiring circuit region 117 may further include external connection lines HL in FIG. 4B surrounded by the ground plate, depending on the design. The ground plate may be spaced apart from the additional wirings by the second insulating layer.

If the terminals SGP and PWP and the second wiring circuit region 117 overlap in the vertical direction (for example, Z-direction), the terminals SGP and PWP and the second wiring circuit region 117 may correspond to both electrodes of a parasitic capacitor, and an insulating layer 116, which is interposed between the two electrodes, may correspond to the dielectric medium of the parasitic capacitor. The larger the area where both electrodes overlap in the vertical direction, the larger the capacitance of the parasitic capacitor may be.

However, since the terminals SGP and PWP and the second conductive layer 117a do not overlap in the vertical direction (for example, Z-direction), the parasitic capacitance (Cap1 in FIG. 1a) of the terminals SGP and PWP may be reduced. Accordingly, the quality (for example, slope distortion, phase distortion, signal integrity, power integrity) of the signal or power passing through the terminals SGP and PWP may be improved.

Each of the positions of the terminals SGP and PWP and the through-hole 117H may be slightly distorted due to variances resulting from the manufacturing process (for example, pattering) for forming the terminals SGP and PWP and the through-hole 117H. The distortion can adversely affect the parasitic capacitance, the parasitic capacitance (Cap1 in FIG. 1A).

In an embodiment of the invention, the through-hole 117H may be configured to be less susceptible to the variances that may result from the manufacturing process. The terminals SGP and PWP are repeatedly arranged in a row arranged in a first direction (for example, Y-direction), and the bonding fingers may have a lengthwise shape along the second direction (for example, X-direction). The length of the through-hole 117H in the first direction (for example, Y-direction) may be longer than the length of the second direction perpendicular to the first direction. Accordingly, since one through-hole 117H may cover a plurality of terminals SGP and PWP together, the through-hole 117H is not substantially affected by any variances that may result from the manufacturing process. The through-hole 117H may stably reduce parasitic capacitance (Cap1 in FIG. 1A).

For example, in some embodiments, the through-hole 117H has a quadrangular shape, and each of the terminals SGP and PWP may have a length in the second direction (for example, X-direction) longer than the length in the first direction (for example, Y-direction). Accordingly, the number of terminals SGP and PWP, which may be covered by one through-hole 117H, may be efficiently increased, and the area of one through-hole 117H may be prevented from becoming too large. As the area of the through-hole 117H is smaller, the stacking stability (for example, delamination) of the second wiring circuit region 117 within the substrate 110 may be improved. The electromagnetic shielding performance of the second wiring circuit region 117 between the upper and lower surfaces of the substrate 110 may be improved.

The through-hole 117H may entirely overlap the bonding fingers SGP and PWP in the vertical direction. An area of the through-hole 117H is smaller than other areas of the second wiring circuit region 117 (i.e., second conductive layer) in a plane (i.e., X-Y plane) view. For example, the overlapping area between the through-hole 117H and the first wiring circuit region 115 the first wiring circuit region 115 in the vertical direction (for example, Z-direction) may be smaller than the overlapping area between the second conductive layer and the first wiring circuit region 115 in the vertical direction (for example, Z-direction). Accordingly, at least one of the grounding stability, electromagnetic shielding performance, and stacking stability of the second wiring circuit region 117 may be improved.

For example, the through-hole 117H may overlap the region between the terminals SGP and PWP in the vertical direction (for example, Z-direction). For example, the through-hole 117H may overlap the region between the signal terminal SGP and the power terminal PWP in the vertical direction (for example, Z-direction). For example, the through-hole 117H may overlap the region between the plurality of signal terminals SGP in the vertical direction. Therefore, since one through-hole 117H may cover a plurality of terminals SGP and PWP together, the through-hole 117H may stably reduce parasitic capacitance (Cap1 in FIG. 1A).

Each of the signal terminals SGP and the signal lines SL may be configured as lanes. The transmitted or received signals may pass through a plurality of electrical paths in a lane together. For example, a transmission lane may include two transmission signal terminals through which signals may be transmitted, and another transmission lane may include two reception signal terminals through which signals may be received. Therefore, the plurality of signal terminals SGP may include at least four signal terminals (at least two lanes). For example, a transmission lane may include two transmission signal lines through which signals may be transmitted, and another transmission lane may include two reception signal lines through which signals may be received. Therefore, the plurality of signal lines SL may include at least 4 signal lines (at least 2 lanes).

Since the plurality of first conductive lines SL and PWL and terminals SGP and PWP may be disposed on the highest metal layer among the plurality of metal layers of the substrate 110, the plurality of first conductive lines SL and PWL and terminals SGP and PWP may not overlap with each other in the vertical direction (for example, Z-direction). For example, the plurality of first conductive lines SL and PWL and terminals SGP and PWP may not be directly connected to a conductive via that penetrates the insulating layer 116.

Referring to FIG. 4A, the through-hole 117H of the semiconductor package 100C according to an example embodiment may be further divided compared to the through-hole 117H of FIG. 3. Referring to FIG. 4B, the through-hole 117H of the semiconductor package 100D according to an example embodiment may be larger than the through-hole 117H of FIG. 3, and may be further expanded in a second direction (for example, X-direction) to overlap a portion of the plurality of first conductive lines SL and PWL in the vertical direction (for example, Z-direction). For example, the shape or size of the through-hole 117H may vary depending on the design.

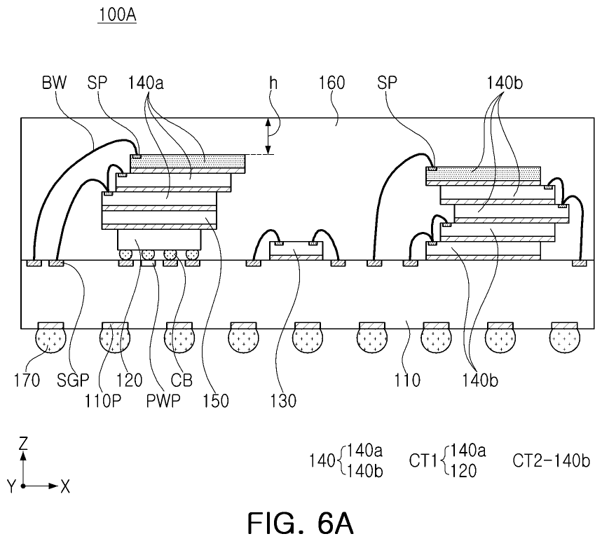

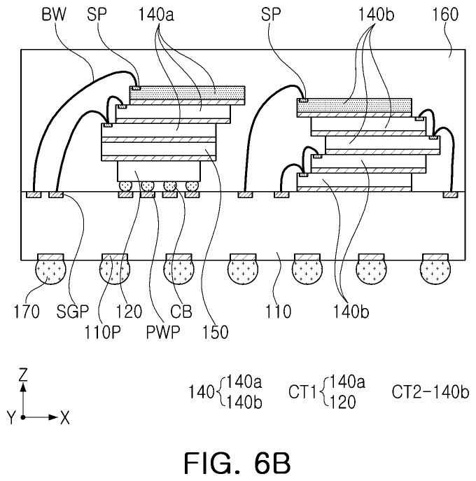

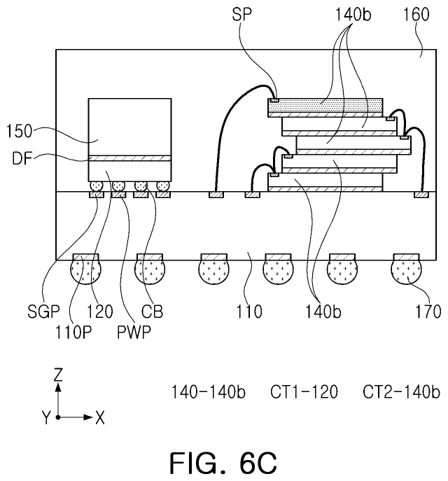

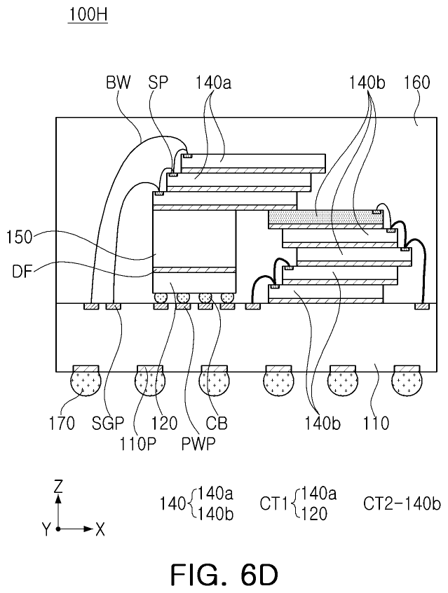

Referring to FIG. 4B, the semiconductor package 100D according to an example embodiment may further include additional wiring in the second conductive layer. For example, the second conductive layer may include a ground plate 117a and external connection lines HL. At least some of the external connection lines HL may be at the same height level as the ground plate 117a and may be spaced apart from the ground plate 117a. The ground plate 117a may be separated from the external connection lines HL by a space 117V. The space 117V may be filled with the second insulating layer. The external connection lines HL may be electrically connected to the external connection terminals 110P and the package bumps 170 disposed on the lower surface of the substrate 110 of FIG. 6A, and may be electrically connected to the chip sets CT1 and CT2. The external connection terminals 110P may be placed at a lower level than the second conductive layer. The chip sets CT1 and CT2 may be electrically connected to the first semiconductor chip 120 disposed lowest of the semiconductor chip set CT1.

As used herein, components described as being “electrically connected” are configured such that an electrical signal can be transferred from one component to the other (although such electrical signal may be attenuated in strength as it is transferred and may be selectively transferred). For example, a component may be referred to as being “electrically connected” to other component through electrical connections by one or more conductors (such as wires, pads, internal electrical lines, through vias, etc.), semiconductor chips (such as controller chips or buffer chips, etc.) and active elements (such as transistors or diodes).

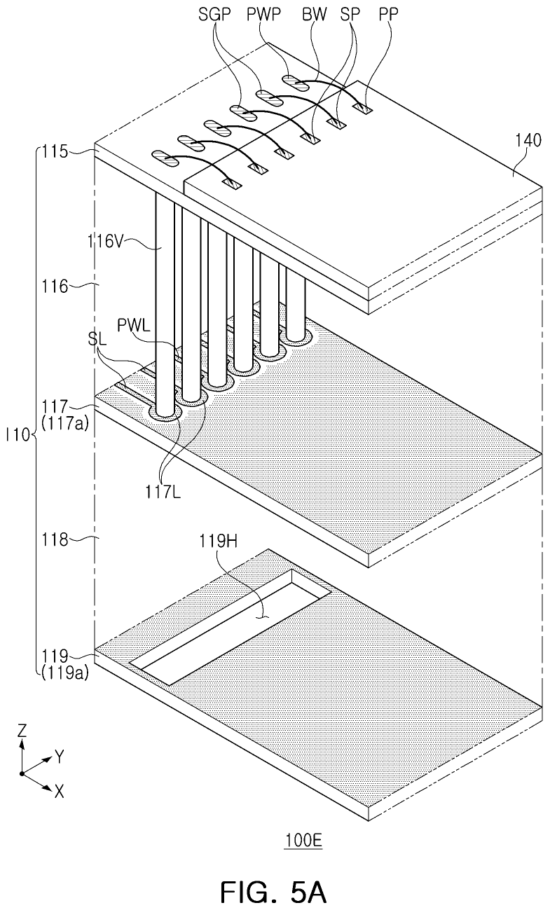

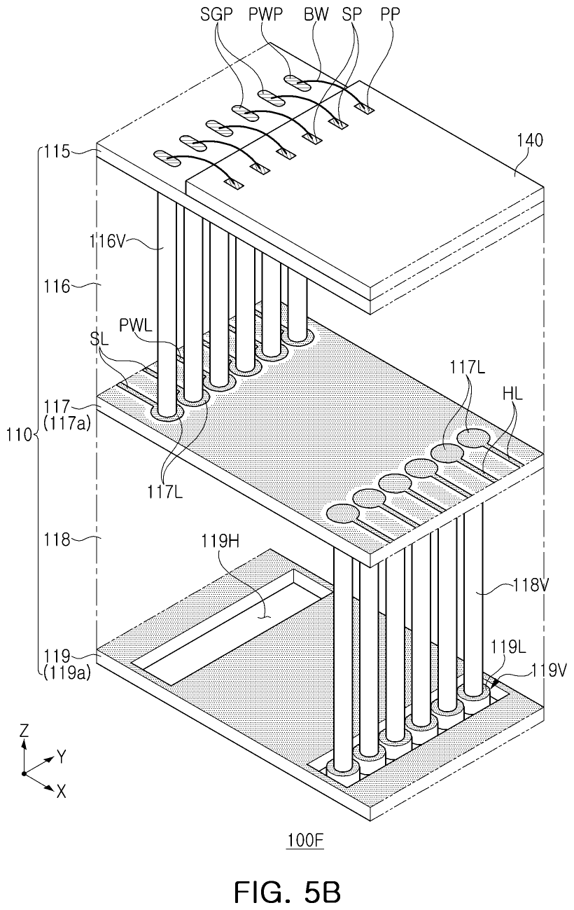

Referring to FIGS. 4B and 5B, the external connection lines HL of the semiconductor packages 100D and 100F according to an example embodiment may not overlap the through-holes 117H and 119H in the vertical direction (for example, Z-direction). Accordingly, signal interference between external connection lines HL and terminals SGP and PWP may be prevented.

Referring to FIGS. 5A and 5B, the substrate 110 of the semiconductor package (100E, 100F) according to an example embodiment may include three or more wiring circuit regions 117 and 119 and two or more insulating layers 116 and 118. The through-hole 119H may be disposed to be lower than the through-hole 117H of FIG. 3. The through-hole 119H may overlap the terminals SGP and PWP in the vertical direction (for example, Z-direction).

Depending on the design, the terminals SGP and PWP may be connected to conductive vias 116V, conductive vias 116V may be connected to a portion of lands 117L, and the lands 117L may be connected to a plurality of first conductive lines SL and PWL. The lands 117L and the first conductive lines SL and PWL may be spaced apart from the second wiring circuit region 117 by the second insulating layer.

The third wiring circuit region 119 may include a third conductive layer, the through-hole 119H in the area and at least portion of a third insulating layer (not shown in the drawings). The third conductive layer and the portion of the third insulating layer may be disposed at a third height level. The third height level is lower than the second height level in the vertical direction. The third conductive layer and the at least portion of the third insulating layer are coplanar with each other. The portion of the third insulating layer may be disposed in a portion of the third wiring circuit region 119 in which the third conductive layer is not formed in a plane view. For example, the through-hole 119H may be filled with the portion of the third insulating layer. The second conductive layer and the portion of the second insulating layer are coplanar.

The external connection lines HL may be electrically connected to the conductive vias 118V through other portions of the lands 117L, and the conductive vias 118V may be connected to lands 119L. Since the third wiring circuit region 119 may provide a separation space 119V to be separated from the lands 119L, the external connection lines HL may be spaced apart from the third conductive layer by the third insulating layer and may be electrically connected to external connection terminals (110P in FIG. 6A) disposed to be lower than the third wiring circuit region 119.

For example, the plurality of insulating layers 116 and 118 may contain insulating materials such as prepreg, Ajinomoto Build-up Film (ABF), Photo Imageable Dielectric (PID), Flame Retardant (FR-4), Bismaleimide Triazine (BT), and epoxy resin. For example, the terminals SGP and PWP, the plurality of first conductive lines SL and PWL, the conductive layers 117a and 119a, and the conductive vias 116V and 118V may include copper (Cu), aluminum (Al), silver (Ag), tin (Sn), gold (Au), nickel (Ni), lead (Pb), titanium (Ti), or alloys thereof.

Meanwhile, referring to FIGS. 1B and 6B, the semiconductor package 100B according to an example embodiment may not include the buffer chip 130 of FIGS. 1A and 6A. For example, the semiconductor package 100A of FIGS. 1A and 6A may include a buffer chip 130.

The buffer chip 130 may buffer command information and address information transmitted and received from the first semiconductor chip 120 and store a queue, and may perform control operations (for example, data processing sequence determination, error and bad sector prevention, loading control, Frequency Boosting Interface (FBI)). The chip sets CT1 and CT2 may perform a write operation or a read operation according to the command information and the address information.

For example, the buffer chip 130 may be electrically connected between at least one semiconductor chip of the second semiconductor chip sets CT2 and the lowermost first semiconductor chip 120 of the first semiconductor chip set CT1, through the substrate 110. The buffer chip 130 does not overlap the lowermost first semiconductor chip 120 in the vertical direction (for example, Z-direction), and may not overlap the second semiconductor chip 140b, in the vertical direction (for example, Z-direction).

Referring to FIG. 6C, the semiconductor package 100G according to an example embodiment may not include most of the semiconductor chips of the first semiconductor chip set CT1 of FIGS. 1A and 6A. Referring to FIG. 6D, the semiconductor package 100H according to an example embodiment may have a structure in which most of the semiconductor chips of the first semiconductor chip set CT1 overlap a portion of the semiconductor chips of the second semiconductor chip set CT2 in the vertical direction (for example, Z-direction). In detail, the structure of the chip sets CT1 and CT2 may vary depending on the design.

As set forth above, in a semiconductor package according to an example, parasitic capacitance may be reduced, thereby improving the quality (for example, at least one of slope distortion, phase distortion, signal integrity, power integrity, and possible data transmission speed) of transmitted/received signals or power of the semiconductor chip.

While example embodiments have been illustrated and described above, it will be apparent to those skilled in the art that modifications and variations could be made without departing from the scope of the present inventive concept as defined by the appended claims.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

1. A semiconductor package comprising:
a substrate including conductive lines, bonding fingers, and a wiring circuit region, wherein the wiring circuit region is disposed lower than the bonding fingers;
bonding wires; and
a first semiconductor chip on the substrate, wherein the first semiconductor chip includes pads disposed on an upper surface thereof, and each of the pads is electrically connected to a first end of a corresponding one of the bonding wires,
wherein the wiring circuit region includes a conductive layer and at least a portion of an insulating layer, the conductive layer and the portion of the insulating layer are disposed at a first height level, and the conductive layer and the portion of the insulating layer are coplanar with each other,
wherein each of second ends of the bonding wires is electrically connected to a corresponding one of the bonding fingers, and
wherein the portion of the insulating layer overlaps the bonding fingers in a vertical direction, and the conductive layer overlaps at least a portion of the conductive lines in the vertical direction.

2. The semiconductor package of claim 1, wherein the portion of the insulating layer overlaps, in the vertical direction, a region between the bonding fingers.

3. The semiconductor package of claim 2, wherein the bonding fingers include:
a signal bonding finger through which a signal is transmitted or received by the first semiconductor chip; and
a power bonding finger through which power is supplied to the first semiconductor chip,
wherein the portion of the insulating layer overlaps, in the vertical direction, a region between the signal bonding finger and the power bonding finger.

4. The semiconductor package of claim 3, wherein the signal bonding finger is one of a plurality of signal bonding fingers, and
the portion of the insulating layer entirely overlaps, in the vertical direction, a region between the plurality of signal bonding fingers.

5. The semiconductor package of claim 1, wherein the bonding fingers include signal bonding fingers through which signals are transmitted or received by the first semiconductor chip, and
wherein the signal bonding fingers are configured to transfer signals having a data transmission rate of 10 Gbps or more.

6. The semiconductor package of claim 1, wherein:
each of the conductive lines is electrically connected to a corresponding one of the bonding fingers,
the conductive lines and the bonding fingers are disposed at the first height level,
the conductive lines and the bonding fingers are coplanar with each other,
the conductive layer includes a through-hole,
the through-hole entirely overlaps, in the vertical direction, a region between the bonding fingers, and
an area of the through-hole is smaller than an area of the conductive layer in a plane view.

7. The semiconductor package of claim 1, wherein the first semiconductor chip is attached to the upper surface of the substrate through an adhesive film, and
the pads and the bonding fingers do not overlap each other in the vertical direction.

8. The semiconductor package of claim 1, further comprising a second semiconductor chip on the substrate,
wherein the first conductive lines allow a signal to be transmitted or received between the first semiconductor chip and the second semiconductor chip.

9. The semiconductor package of claim 8, wherein the first semiconductor chip is one of a plurality of first semiconductor chips at least partially overlapping each other in the vertical direction,
the second semiconductor chip is one of a plurality of second semiconductor chips at least partially overlapping each other in the vertical direction, and
a lowermost first semiconductor chip among the plurality of first semiconductor chips is mounted on the upper surface of the substrate with a flip-chip bonding structure.

10. The semiconductor package of claim 9, further comprising a buffer chip electrically connected between at least one of the plurality of second semiconductor chips and the lowermost first semiconductor chip among the plurality of first semiconductor chips, through the substrate,
wherein the buffer chip does not overlap the lowermost first semiconductor chip among the plurality of first semiconductor chips in the vertical direction, and does not overlap a lowermost second semiconductor chip among the plurality of second semiconductor chips in the vertical direction.

11. The semiconductor package of claim 9, wherein the substrate further includes:
external connection terminals disposed to be lower than the conductive layer; and
external connection lines electrically connected between the external connection terminals and the lowermost first semiconductor chip among the plurality of first semiconductor chips,
wherein the external connection lines overlap the conductive layer in the vertical direction.

12. The semiconductor package of claim 1, wherein the substrate further includes:
external connection terminals disposed to be lower than the conductive layer; and
external connection lines electrically connected to the external connection terminals,
wherein the external connection lines overlap the conductive layer in the vertical direction.

13. The semiconductor package of claim 12, wherein:
the bonding fingers are arranged repeatedly in a row in a first direction,
the lower conductive pattern includes a through-hole, and
a length of the through-hole in the first direction is longer than a length of the through-hole in a second direction, perpendicular to the first direction.

14. The semiconductor package of claim 13, wherein the through-hole has a quadrangular shape, and
each of the bonding fingers has a lengthwise shape along the second direction.

15. (canceled)

16. (canceled)

17. A semiconductor package comprising:
a substrate including:
bonding fingers;
conductive lines; and
a conductive layer including a through-opening, wherein each of the conductive lines is electrically connected to a corresponding one of the bonding fingers; and
a first semiconductor chip on the substrate and electrically connected to the bonding fingers,
wherein:
the through-opening overlaps the bonding fingers in a vertical direction,
the bonding fingers are arranged repeatedly in a row in a first direction, and
a length of the through-opening in the first direction is longer than a length of the through-opening in a second direction, perpendicular to the first direction.

18. The semiconductor package of claim 17, wherein the bonding fingers comprise:
a plurality of signal bonding fingers through which a plurality of respective signals are transmitted or received by the first semiconductor chip; and
a power bonding finger through which power is supplied to the first semiconductor chip,
wherein the through-opening overlaps, in a vertical direction, a region between one of the signal bonding fingers and the power bonding finger, and a region between the plurality of signal bonding fingers.

19. The semiconductor package of claim 17, wherein:
each of the conductive lines is connected to a corresponding one of the bonding fingers,
the conductive lines and the bonding fingers are disposed at the same height level,
the first semiconductor chip is attached to an upper surface of the substrate through an adhesive film, and
an area of the through-opening is smaller than an area of the conductive layer in a plane view.

20. The semiconductor package of claim 17, further comprising a second semiconductor chip on the substrate, wherein:
the conductive lines allow a signal to be transmitted or received between the first semiconductor chip and the second semiconductor chip,
the first semiconductor chip is one of a plurality of first semiconductor chips at least partially overlapping each other in the vertical direction,
the second semiconductor chip is one of a plurality of second semiconductor chips at least partially overlapping each other in the vertical direction,
a lowermost second semiconductor chip among the plurality of second semiconductor chips is attached to an upper surface of the substrate through an adhesive film, and
a lowermost first semiconductor chip among the plurality of first semiconductor chips is mounted on the upper surface of the substrate with a flip-chip bonding structure.

21. A semiconductor package comprising:
a substrate including:
bonding fingers arranged repeatedly in a row in a first direction;
conductive lines, wherein each of the conductive lines is electrically connected to a corresponding one of the bonding fingers;
a conductive layer overlapping a portion of the conductive lines in a vertical direction, wherein the conductive layer includes a through-hole overlapping the bonding fingers in the vertical direction;
an insulating layer, wherein at least portion of the insulating layer and the conductive layer are disposed at the same height level;
external connection terminals disposed to be lower than the conductive layer; and
external connection lines electrically connected to the external connection terminals, the external connection lines not overlapping the through-hole in the vertical direction;
bonding wires, each of which having a first end electrically connected to a corresponding one of the bonding fingers; and
a first semiconductor chip on the substrate, the first semiconductor chip including pads, wherein each of the pads is electrically connected to a second end of a corresponding one of the bonding wires,
wherein the bonding fingers include:
a plurality of signal bonding fingers, through each of which a signal is transmitted or received by the first semiconductor chip; and
a power bonding finger through which power is supplied to the first semiconductor chip, and
wherein the through-hole overlaps, in the vertical direction, a region between the power bonding finger and an adjacent signal bonding finger and a region between the plurality of signal bonding fingers, and an area of the through-hole of the conductive layer is smaller than an area of a remaining portion of the second conductive layer in a plane view.

22. The semiconductor package of claim 21, further comprising a second semiconductor chip on the substrate, wherein:
the conductive lines allow a signal to be transmitted or received between the first semiconductor chip and the second semiconductor chip,
the first semiconductor chip is one of a plurality of first semiconductor chips at least partially overlapping each other in the vertical direction,
the second semiconductor chip is one of a plurality of second semiconductor chips at least partially overlapping each other in the vertical direction,
a lowermost second semiconductor chip among the plurality of second semiconductor chips is attached to an upper surface of the substrate through an adhesive film, and
a lowermost first semiconductor chip among the plurality of first semiconductor chips is mounted on the upper surface of the substrate with a flip-chip bonding structure.
